(19) United States
(12) Patent Application Publication
(10) Pub. No.: US 2015/0163925 A1
(43) Pub. Date: Jun. 11, 2015

(54) ELECTRONIC COMPONENT MOUNTING METHOD AND ELECTRONIC COMPONENT MOUNTING SYSTEM

(71) Applicant: PANASONIC INTELLECTUAL PROPERTY MANAGEMENT CO., LTD., Osaka (JP)

(72) Inventors: Hachiro NAKATSUJI, Yamanashi (JP); Kenji OKAMOTO, Yamanashi (JP)

(21) Appl. No.: 14/561,396

(22) Filed: Dec. 5, 2014

(30) Foreign Application Priority Data
Dec. 6, 2013 (JP) 2013-252647

(51) Int. Cl. H05K 3/34; B23K 1/00; B23K 3/06

(52) U.S. Cl. CPC H05K 3/341; H05K 3/3452; H05K 3/3484; H05K 3/3436; B23K 3/0638; B23K 1/0016

(57) ABSTRACT

An electronic component mounting system includes a screen printing apparatus, a coating unit and an electronic component mounting apparatus. The screen printing apparatus supplies a solder paste to first specific lands of a board, using a mask plate that includes a stepped portion and pattern holes formed so as to correspond to the first specific lands. The coating unit coats the solder paste on second specific lands of the board which are positioned in a region of the board overlapping the stepped portion of the mask plate and a vicinity of the stepped portion when the screen printing apparatus supplies the solder paste using the mask plate. The electronic component mounting apparatus mounts the electronic components on the first and second specific lands to which the solder paste is supplied through the screen printing apparatus and the coating unit.

### CROSS REFERENCE TO RELATED APPLICATIONS

This application is based upon and claims the benefit of priority of Japanese Patent Application No. 2013-252647 filed on Dec. 6, 2013, the contents of which are incorporated herein by reference in its entirety.

### BACKGROUND OF THE INVENTION

1. Field of the Invention

The present invention relates to an electronic component mounting method and an electronic component mounting system of mounting electronic components on lands provided on a board using a paste.

2. Description of the Related Art

In an electronic component mounting step, screen printing is used as a method of supplying a solder paste to lands provided on a board. In this method, a mask plate provided with pattern holes corresponding to the lands is brought into contact with the board, the solder paste is supplied onto the mask plate, a squeegee is slid against the mask plate, and thereby the solder paste is printed on the board via the pattern holes. The board having the solder paste printed thereonto is sent to a subsequent electronic component mounting step, and electronic components are mounted on the board.

In a surface mounting method used in recent years, electronic components having considerably different sizes may be mounted on the board, and the range of the electronic components is from tiny chip components of a 0402 size or the like to large components such as a relatively large chip electrolytic capacitor or a power electronic component. The sizes of the lands provided on the board become considerably different depending on the type and size of electronic components, and the necessary amounts of a solder become extremely different depending on the sizes of the lands. In typical screen printing, the solder paste is printed on the lands, using a single mask plate with a uniform thickness, but when the necessary amounts of a solder are extremely different, it is considerably difficult to perform the screen printing using the single mask plate with the uniform thickness. For this reason, proposed is a paste printing method of using mask plates with different thicknesses for a region in which the fine lands are highly densely mounted, and a region in which the fine lands are not highly densely mounted (for example, refer to JP-A-5-212852 and JP-A-2005-138341).

In an example illustrated in JP-A-5-212852, a first step is performed in which the paste is printed on the board, using a first mask plate with a small thickness, and then a second step is performed in which the paste is printed on the board, using a second mask plate with a large thickness. A concave portion is provided on a back surface of the second mask plate, and is positioned to correspond to the paste printed on the board in the first step, and when the second step is performed, paste portions formed on the lands in the first step can be prevented from interfering with the second mask plate.

In an example illustrated in JP-A-2005-138341, the mask plate is provided with a stepped portion in which the thickness is changed, and a plurality of pattern holes are formed in the mask plate, the thickness of which is changed, and are positioned to correspond to the lands on the board. Since the screen printing is performed using the mask plate with this shape, it is possible to form the paste portions having different thicknesses on the lands at the same time, and improve productivity.

### SUMMARY OF THE INVENTION

However, in the example illustrated in JP-A-5-212852, there is a problem in having to prepare two pieces of mask plates with different thicknesses. There is a problem in that when the positioning error of the printing occurs in the first step, it is difficult to prevent the paste portions formed on the lands from interfering with the second mask plate depending on a degree of the positioning error, and thus the screen printing has a very high degree of difficulty. Since it is necessary to secure the rigidity of the second mask plate, in a design stage of the board, there are certain limitations to the number of lands or the disposition of the lands which become printing targets in the first step.

There is a problem in that the mask plate disclosed in JP-A-2005-138341 has the stepped portion in which the thickness is changed, and printing failure is likely to occur in the vicinity of the stepped portion. Accordingly, the board has a design limitation that it is not possible to form the lands in a region which is expected to be the vicinity of the stepped portion of the mask plate, and due to this limitation, it is not possible to dispose the electronic components at high density.

A non-limited object of the present invention is to provide an electronic component mounting method and an electronic component mounting system by which it is possible to solve the problems.

An aspect of the present invention provides an electronic component mounting method of using a solder paste to mount electronic components on a board provided with a plurality of first lands included in a first group and a plurality of second lands included in a second group, the method including: supplying the solder paste to the board, using a mask plate which includes a first part, a second part having a different thickness from that of the first part, and a stepped portion that is a boundary between the first part and the second part, and includes pattern holes formed so as to correspond to the plurality of first lands in the first and second parts; supplying the solder paste to the plurality of second lands, using a coating unit for coating the solder paste; and mounting the electronic components on the first and second lands to which the solder paste is supplied, wherein the second lands included in the second group are disposed in a region of the board, which overlaps the stepped portion of the mask plate and a vicinity of the stepped portion, when the solder paste is supplied using the mask plate.

Another aspect of the present invention provides an electronic component mounting system using a solder paste to mount electronic components on a board provided with a plurality of lands, the system including: a screen printing apparatus that supplies the solder paste to a plurality of first specific lands of the board, using a mask plate that includes a first part, a second part having a different thickness from that of the first part, and a stepped portion that is a boundary between the first part and the second part, and includes pattern holes formed so as to correspond to the plurality of first specific lands in the first and second parts; a coating unit which coats the solder paste on a plurality of second specific lands of the board which are positioned in a region of the board, the region overlapping the stepped portion of the mask plate and a vicinity of the stepped portion when the screen printing apparatus supplies the solder paste using the mask plate; and an electronic component mounting apparatus that mounts the electronic components on the first and second specific lands to which the solder paste is supplied through the screen printing apparatus and the coating unit.

According to the aspects of the present invention, it is possible to mount electronic components at high density and with high quality, and improve productivity.

### BRIEF DESCRIPTION OF THE DRAWINGS

In the accompanying drawings:

FIG. 1 is an entire configuration view of an electronic component mounting system according to an embodiment of the present invention;

FIG. 2 is a front view of a screen printing apparatus of the electronic component mounting system according to the embodiment of the present invention;

FIG. 3 illustrates cross-sectional views of a mask plate and a board that are provided in the screen printing apparatus of the electronic component mounting system according to the embodiment of the present invention;

FIG. 4 is a plan view of a solder coating apparatus of the electronic component mounting system according to the embodiment of the present invention;

FIG. 5 is a diagram illustrating the structure of a dispenser provided in the solder coating apparatus of the electronic component mounting system according to the embodiment of the present invention;

FIG. 6 is a plan view of an electronic component mounting apparatus of the electronic component mounting system according to the embodiment of the present invention;

FIG. 7 is a flowchart of electronic component mounting steps according to the embodiment of the present invention;

FIGS. 8A to 8G are diagrams illustrating the electronic component mounting steps according to the embodiment of the present invention;

FIG. 9 is a cross-sectional view illustrating a relationship between the mask plate and the board provided in the screen printing apparatus of the electronic component mounting system according to the embodiment of the present invention; and

FIGS. 10A and 10B are cross-sectional views of mask plates provided in the screen printing apparatus of an electronic component mounting system according to other embodiments of the present invention.

### DETAILED DESCRIPTION OF THE EXEMPLARY EMBODIMENTS

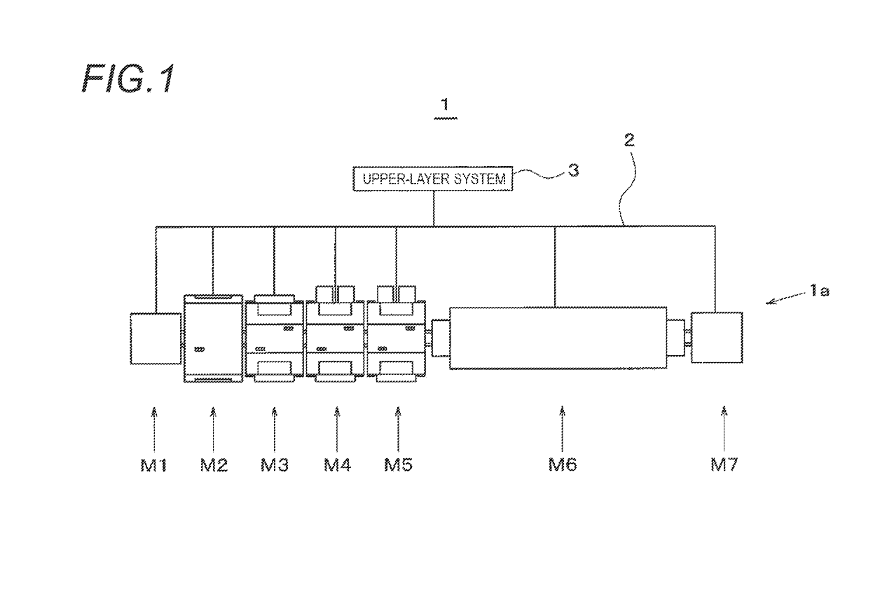

First, an electronic component mounting system according to an embodiment of the present invention will be described with reference to FIG. 1. An electronic component mounting system 1 serves to mount electronic components using a solder paste (a paste obtained by mixing solder particles and flux, and hereinafter, simply referred to as a “solder”) for bonding the components to lands (electrodes) provided on a board. The electronic component mounting system 1 includes an electronic component mounting line la as a main body in which a plurality of component mounting apparatuses are connected in series to each other in an X direction (board transportation direction), and the component mounting apparatuses include a board supply apparatus M1; a screen printing apparatus M2; a solder coating apparatus M3; a first electronic component mounting apparatus M4; a second electronic component mounting apparatus M5; a reflow apparatus M6; and a board collection apparatus M7. Each of the component mounting apparatuses M1 to M7 are connected to an upper layer system 3 via a communication network 2 such as a local area network, and the upper layer system 3 has a management computer.

The board supply apparatus M1 supplies a board on which the electronic components are to be mounted. The screen printing apparatus M2 supplies the solder to predetermined lands of a plurality of the lands provided on the board via screen printing. The solder coating apparatus M3 supplies the solder to lands to which the solder is supplied through the screen printing apparatus M2, via coating using a dispenser that will be described later. The first electronic component mounting apparatus M4 and the second electronic component mounting apparatus M5 mount the electronic components on the board to which the solder is supplied. The reflow apparatus M6 melts and solidifies the solder by heating the board with the electronic components mounted thereonto per a predetermined heating profile. Accordingly, it is possible to complete a mounted board onto which the electronic components are solder-bonded. The board collection apparatus M7 collects the mounted board.

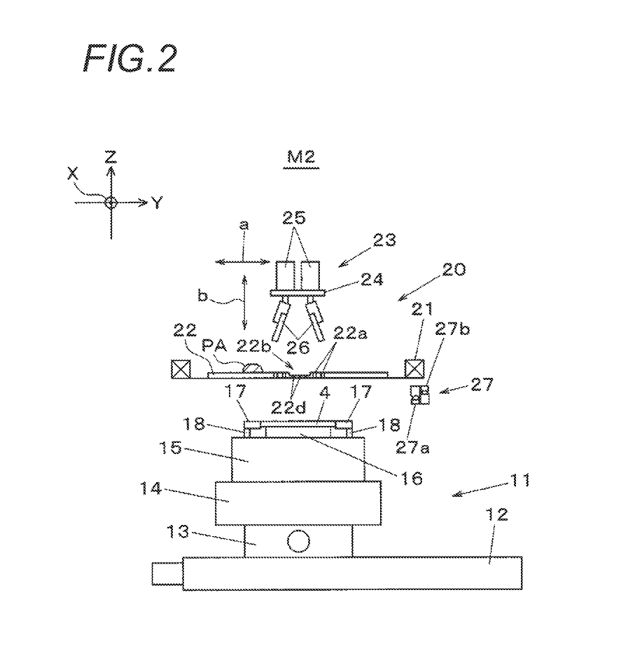

Subsequently, the screen printing apparatus M2 will be described with reference to FIG. 2. The screen printing apparatus M2 has a configuration in which a screen printing unit 20 is provided above a board positioning unit 11. The board positioning unit 11 serves to hold a board 4 supplied from an upstream apparatus, and locates the board 4 at a predetermined printing position, and has a configuration in which a Y-axis table 12, an X-axis table 13, and an O-axis table 14 are stacked on each other, and a Z-axis table 15 is installed thereon. A board support unit 16 is provided on the Z-axis table 15 so as to receive the board 4 and support a lower surface of the board 4.

A pair of transportation conveyors 18 are provided above the board positioning unit 11 in the X direction. Clamps 17 are respectively provided on the transportation conveyors 18 so as to be movable in the X direction and a Y direction orthogonal to the X direction in a horizontal plane. The board 4 is transported onto the board support unit 16 from an upstream side by the transportation conveyors 18, and is interposed between the clamps 17, and the position of the board 4 is fixed. The board support unit 16 and the clamps 17 form a board holding unit for holding the board 4. The driving of the Z-axis table 15 moves the transportation conveyors 18, the clamps 17, and the board support unit 16 up and down in a vertical direction (Z direction) together with the board 4 held.

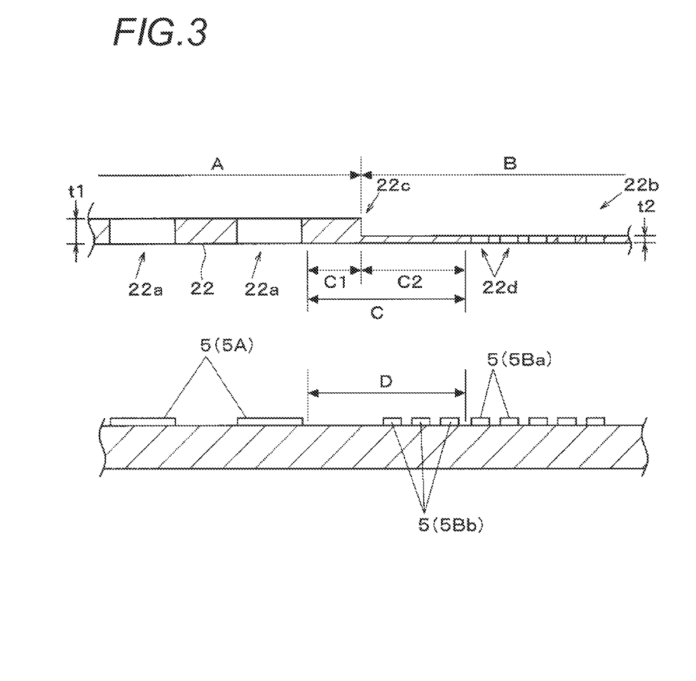

The screen printing unit 20 includes a mask plate 22 deployed in a mask frame 21. In FIG. 3, the mask plate 22 is made of a material of a thickness t1. A plurality of pattern holes 22a are formed in the mask plate 22 so as to supply a solder PA (refer to FIG. 2) to relatively large lands 5A among a plurality of lands 5 that are provided on the board 4.

A concave portion 22b is partially formed in the mask plate 22, and has a thickness t2 which is less than the thickness t1. The mask plate 22 includes a first part A having the thickness t1, and a second part B having a different thickness from that of the first part A. The mask plate 22 includes a stepped portion 22c that is a boundary between the first part A and the second part B.

A plurality of pattern holes 22d are formed in the concave portion 22b so as to allow printing of the solder PA on lands 5B that are smaller than the lands 5A among the plurality of lands 5 provided on the board 4. The examples of the land 5B include a land for soldering very small components such as so-called 0402 and 0603 components, and a land for bonding a bump such as a BGA or a CSP having a bump pitch of 0.3 mm or smaller. Accordingly, an opening area of the pattern hole 22d is smaller than that of the pattern hole 22a, and the amount of the solder PA supplied via the pattern hole 22d is also smaller than that supplied via the pattern hole 22a. The pattern holes 22a and 22d are formed in the mask plate 22 so as to correspond to the specific lands 5A and 5B, respectively.

In FIG. 2, a printing head 23 equipped with squeegees 26 is provided above the mask plate 22. The printing head 23 has a configuration in which a squeegee lifting mechanism 25 for lifting the squeegees 26 up and down is provided on a moving base 24 that is movable in the Y direction. A squeegee moving mechanism (not illustrated) moves the printing head 23 horizontally and in the Y direction (along an arrow a). The squeegee lifting mechanism 25 is driven to lift the squeegees 26 up and down (along an arrow b) and bring the squeegees 26 into contact with an upper surface of the mask plate 22.

When the solder PA is supplied to the board 4, the Z-axis table 15 is driven to lift the board 4 up and bring the board 4 into contact with a lower surface of the mask plate 22. The squeegee moving mechanism is driven to perform a squeegeeing operation of sliding the squeegees 26 against the upper surface of the mask plate 22 in the Y direction, the solder PA being supplied to the upper surface of the mask plate 22. During the squeegeeing operation, the squeegees 26 push the solder PA into the pattern holes 22a and 22d. Accordingly, the solder PA is screen printed on the specific lands 5A and 5B via the respective pattern holes 22a and 22d.

In the screen printing, it is important to maintain a filling pressure within a predetermined range, and the filling pressure is a pressure at which the squeegees 26 push the solder PA into the pattern holes 22a and 22d, and fill the pattern holes 22a and 22d with the solder PA. Since the height of the upper surface of the mask plate 22 is changed at the position of the stepped portion 22c, as illustrated in FIG. 3, a filling pressure in the stepped portion 22c and a region C in the vicinity of the stepped portion 22c may change, and exceed the predetermined range. For this reason, when the screen printing is performed with the pattern holes 22a and 22d formed in the region C, printing failure, for example, “blur” in which the solder is insufficiently supplied to the lands 5 that correspond to the pattern holes 22a and 22d in the region C, is highly likely to occur.

As such, the stepped portion 22c formed in the mask plate 22 and the region C in the vicinity of the stepped portion 22c become unstable regions, the printing quality of which is unstable. The region (C) is referred to as an “unstable region” in the following description. In FIG. 3, in the mask plate 22, the unstable region C can be divided into a first unstable region C1 in the first part A and a second unstable region C2 in the second part B. In the mask plate 22, the first unstable region C1 is continuous with the second unstable region C2 via the stepped portion 22c. The unstable region C is empirically determined, and the first unstable region C1 and the second unstable region C2 may have the same size.

The pattern holes 22a and 22d are respectively formed in the first part A and the second part B but not in the unstable region C. The screen printing apparatus M2 prints the solder PA on only the lands 5A and 5Ba that correspond to the pattern holes 22a and 22d, respectively. When the mask plate 22 and the board 4 are aligned with each other so as to perform the screen printing, the solder coating apparatus M3 supplies the solder to lands 5Bb provided in a region D of the board 4, which overlaps the unstable region C. For this reason, the mask plate 22 is not provided with pattern holes that correspond to the lands 5Bb.

In the embodiment, the lands 5A and 5Ba, and the lands 5Bb are divided into a first group and a second group, respectively. The lands 5A and 5Ba are objects for the operation of the screen printing apparatus M2, and the lands 5Bb are objects for the operation of the solder coating apparatus M3. The lands 5A and 5Ba are classified as first lands included in the first group, and the lands 5Bb are classified as second lands included in the second group.

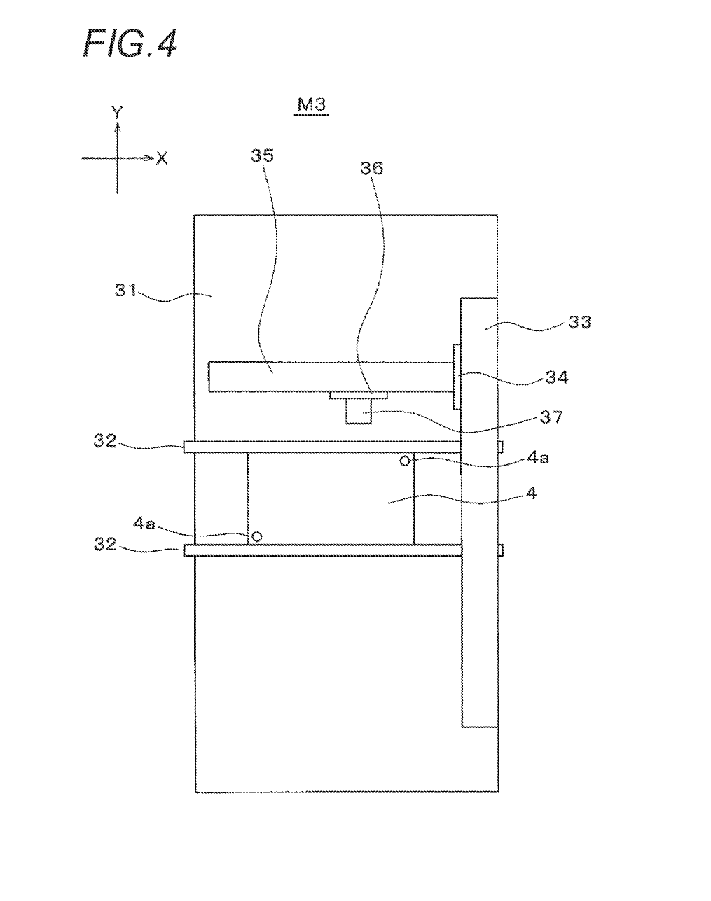

In FIG. 2, a camera head unit 27 is provided below the mask plate 22 and is horizontally movable. The camera head unit 27 includes a board identification camera 27a and a mask identification camera 27b. The board identification camera 27a captures an image of a board identification mark 4a (refer to FIG. 4) from above, and the board identification mark 4a is formed on each corner portion on a diagonal line of the board 4. The mask identification camera 27b captures an image of mask identification marks (not illustrated) from below, and the mask identification marks are formed on the mask plate 22, and positioned to correspond to the board identification marks 4a, respectively. The movement of the camera head unit 27 allows the board identification camera 27a and the mask identification camera 27b to move to a position that corresponds to the positions of the board identification mark 4a and the mask identification mark, and to capture the images of the board identification mark 4a and the mask identification mark, respectively. The captured images are sent to a process unit that is not illustrated, and the process unit performs an identification process of the board identification mark 4a and the mask identification mark. The board positioning unit 11 moves the board 4 held by the board holding unit, based on a result of the identification process, and thus aligns the board 4 and the mask plate 22 with each other in a horizontal plane.

Subsequently, the solder coating apparatus M3 will be described with reference to FIG. 4. A pair of transportation conveyors 32 are provided on a base 31 in the X direction. The transportation conveyors 32 receive the board 4 from the upstream screen printing apparatus M2, transport the board 4 to a predetermined coating operation position, and locate the board 4 at the predetermined coating operation position. A Y-axis table 33 having a linear drive mechanism is provided in one end portion of the base 31 in the X direction, and is horizontal in the Y direction. A joint bracket 34 is installed on the Y-axis table 33, and slidable in the Y direction. An X-axis table 35 is joined to the joint bracket 34, and is provided with a linear drive mechanism similar to the Y-axis table 33.

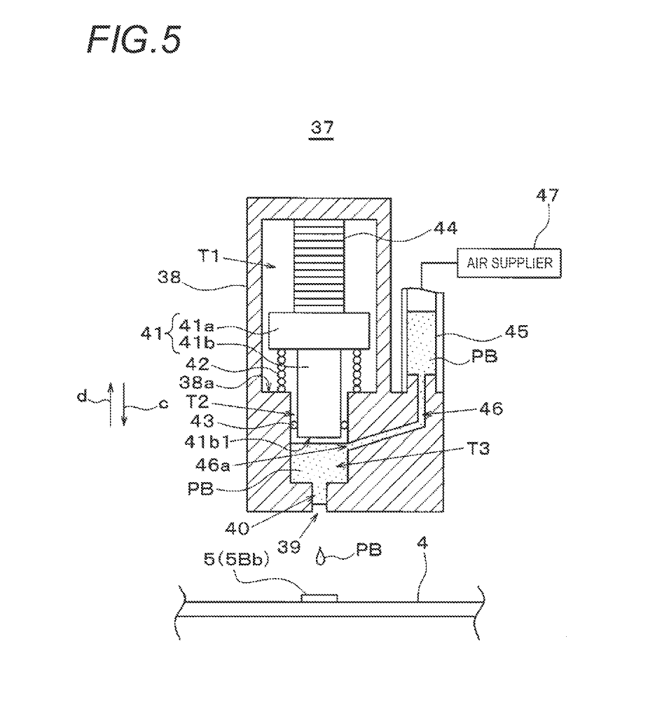

A joint bracket 36 is installed on the X-axis table 35, and slidable in the X direction, and a dispenser 37 is attached to the joint bracket 36. The dispenser 37 serves to supply the solder PB (refer to FIG. 5) to the second lands 5Bb via an injection method, and the X-axis table 35 and the Y-axis table 33 move the dispenser 37 in the X and Y directions. The Y-axis table 33 and the X-axis table 35 are moving mechanisms to horizontally move the dispenser 37.

The structure of the dispenser 37 will be described with reference to FIG. 5. A main body portion 38 of the dispenser 37 is provided with a first space T1 and a second space T2 that has a length smaller than that of the first space T1 in a lateral direction. The first space T1 vertically communicates with the second space T2. A discharge port 39 is formed in a lower surface of the main body portion 38, and communicates with the second space T2 via a communication path 40.

A T-shaped plunger 41 is provided in the first space T1. The plunger 41 includes a flange portion 41a that extends horizontally, and a shaft portion 41b that extends downward from substantially the center of the flange portion 41a. A spring member 42 is provided between the flange portion 41a and an upper surface 38a of the main body portion 38, and the upper surface 38a forms a lower end of the first space T1. The spring member 42 biases the plunger 41 upward. A part of the shaft portion 41b of the plunger 41 penetrates into the second space T2, the part of the shaft portion 41b including a lower end portion 41b1 thereof, and a third space T3 is formed below the shaft portion 41.b.

In the second space T2, a ring-shaped sealing member 43 is provided in a gap between an outer circumferential surface of the shaft portion 41b and an inner surface of the main body portion 38 which faces the outer circumferential surface. The sealing member 43 blocks the solder PB that is pushed upward when pressure is applied to a compression chamber (to be described later), and serves to prevent the solder PB from flowing into the first space T1.

Laminated voltage elements 44 are provided on an upper surface of the flange portion 41a, and is made by laminating a plurality of voltage elements in the vertical direction. The laminated voltage elements 44 are displaced in a laminating direction of the voltage elements when voltage is applied thereto. Accordingly, the plunger 41 moves downward (along an arrow c) against an upward biasing force caused by the spring member 42, and thus a predetermined pressure is applied to the third space T3. As such, the third space T3 functions as the compression chamber. When a voltage is not applied to the laminated voltage elements 44, the plunger 41 is biased and moved upward (along an arrow d) by the spring member 42.

A solder reservoir unit 45 is provided on a side portion of the main body portion 38, and stores a paste-like solder PB therein. A conduit 46 is provided from a lower surface of the solder reservoir unit 45 to the third space T3 (compression chamber), and the solder PB stored in the solder reservoir unit 45 is supplied to the third space T3 via the conduit 46. When voltage is not applied to the laminated voltage element 44, a connection port 46a between the conduit 46 and the third space T3 is positioned downward of the shaft portion 41b.

The solder reservoir unit 45 is connected to an air supplier 47. When air is supplied to the solder reservoir unit 45 from the air supplier 47, the solder PB is delivered to the conduit 46. Accordingly, the solder PB is supplied to the third space T3, that is, the compression chamber via the conduit 46. The solder PB stored in the solder reservoir unit 45 may be the same as the solder PA used by the screen printing apparatus M2.

When the plunger 41 moves downward in a state where the solder PB is supplied to the compression chamber, the solder PB in the third space T3 is pressurized, and is pushed into the communication path 40, and a lump of the solder PB similar to a droplet is discharged downward from the discharge port 39. Accordingly, the solder PB can be supplied to the second lands 5Bb that are positioned below the discharge port 39. A very small amount of the solder PB is discharged at a time, and the dispenser 37 adjusts the amount of the solder supplied to the second lands 5B by changing the frequency of discharge. For this reason, the dispenser 37 is suitable for supplying the solder PB in small amounts. The dispenser 37 is coating unit for coating the solder paste on a plurality of other specific lands 5 (the second lands 5Bb) of the board 4, to which the solder paste is supplied through the screen printing apparatus M2, and which are positioned in a region of the board 4, the region overlapping the stepped portion 22c of the mask plate 22 and the vicinity of the stepped portion 22c when the screen printing apparatus M2 supplies the solder paste.

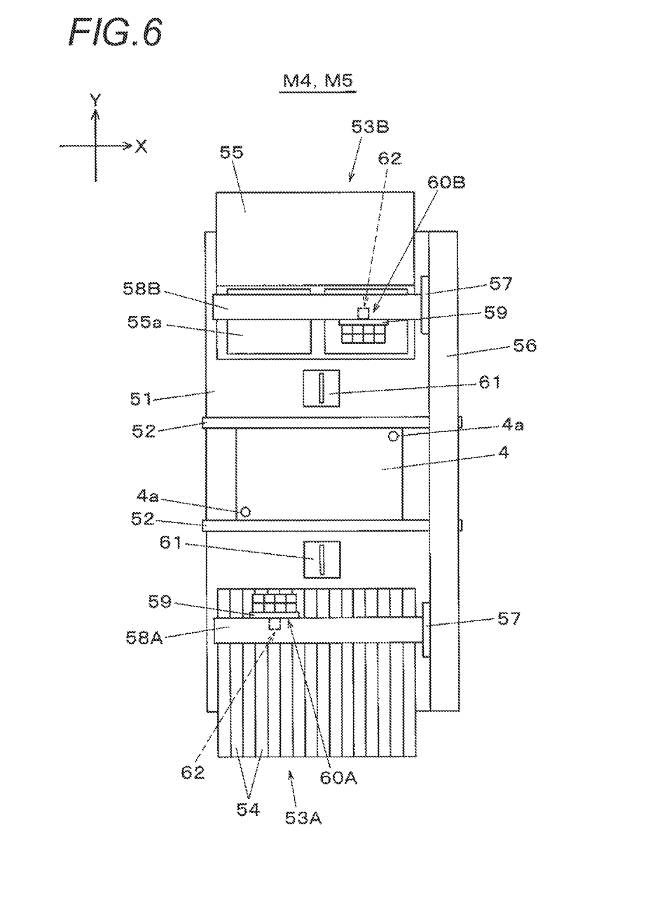

Subsequently, the first electronic component mounting apparatus M4 and the second electronic component mounting apparatus M5 will be described with reference to FIG. 6. The electronic component mounting apparatuses M4 and M5 will be indiscriminately described due to having the same structure. A pair of transportation conveyors 52 are provided on a base 51 in the X direction. After the solder is supplied to the board 4, the transportation conveyors 52 transport the board 4 and locate the board 4 at a predetermined mounting operation position. Component supply units 53A and 53B are provided on opposite sides of the transportation conveyors 52. A plurality of tape feeders 54 are disposed in the component supply unit 53A, and a tray feeder 55 is disposed in the component supply unit 53B.

A carrier tape is installed on the tape feeder 54, and stores small electronic components such as so-called 0402 and 0603 components. The tape feeder 54 supplies the electronic components to a mounting head 60A by pitch-feeding the carrier tape. The tray feeder 55 accommodates a tray 55a in which large electronic components such as a BGA and a GSP are stored in a grid array. The tray feeder 55 supplies the electronic components to a mounting head 60B by moving the tray 55a to a component unloading position at which the electronic components are unloaded by the mounting head 60B.

The type of the feeder disposed in each of the component supply units 53A and 54B is changed depending on the board 4 that is a mounted object. For example, the tape feeders 54 may be disposed in both the component supply unit 53A and 54B. The type or disposition of the feeder may be switched between the first electronic component mounting apparatus M4 and the second electronic component mounting apparatus M5.

A Y-axis table 56 having a linear drive mechanism is provided in one end portion of the base 51 in the X direction, and is horizontal in the Y direction, and two joint brackets 57 are installed on the Y-axis table 56, and slidable in the Y direction. Two X-axis tables 58A and 58B are respectively joined to the joint brackets 57, and each of the X-axis tables 58A and 58B is provided with a linear drive mechanism similar to the Y-axis table 56. Joint brackets 59 are respectively installed on the X-axis tables 58A and 58B, and slidable in the X direction, and the mounting heads 60A and 60B are respectively attached to the joint brackets 59.

A suction nozzle (not illustrated) is installed in a lower end portion of each of the mounting heads 60A and 60B so as to suction and hold the electronic component, and a nozzle lifting mechanism built in each of the mounting heads 60A and 60B lifts the suction nozzle up and down. The X-axis tables 58A and 5813 and the Y-axis table 56 move the mounting heads 60A and 60B in the X and Y directions. Accordingly, the mounting head 60A unloads the electronic components from the tape feeder 54, and mounts the electronic components on the board 4. The mounting head 60B unloads the electronic components from the tray feeder 55, and mounts the electronic components on the board 4.

A component identification apparatus 61 is provided between the component supply unit 53A and the transportation conveyor 52, and the component supply unit 53B and the transportation conveyor 52. The component identification apparatus 61 identifies the electronic components by capturing images of the electronic components from below, which are respectively unloaded from the component supply units 53A and 53B and held by the mounting heads 60A and 60B. A board identification camera 62 is attached to each of the mounting heads 60A and 60B. The board identification camera 62 captures an image of the board identification mark 4a of the board 4 at the mounting operation position. The process unit (not illustrated) performs an identification process of the captured image. After positional correction is performed so as to align the mounting heads 60A and 60B with the board 4, based on a detected positional deviation result, the electronic components are mounted on the board 4.

In the embodiment, the first electronic component mounting apparatus M4 includes the two mounting heads 60A and 60B, and when any one of the mounting heads 60A and 60B is replaced with the dispenser 37, the dispenser 37 may be disposed in the first electronic component mounting apparatus M4 in a state where the dispenser 37 is attached to any one of the two joint brackets 59.

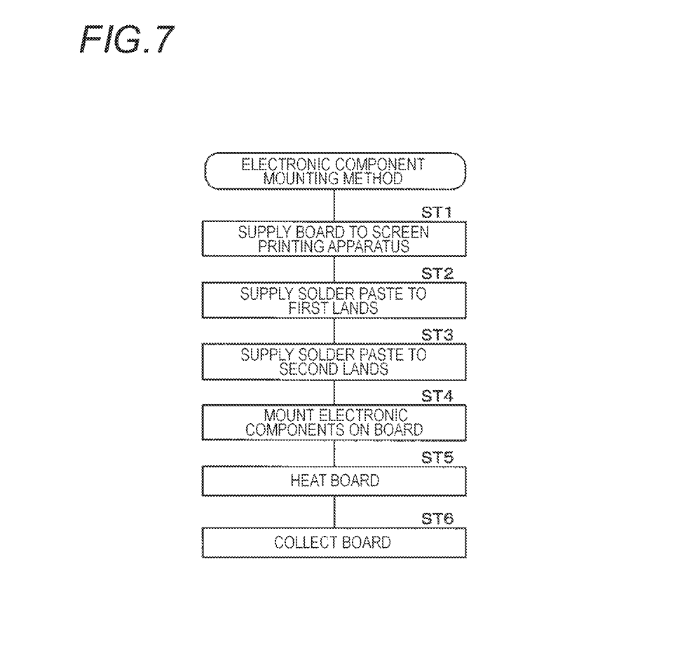

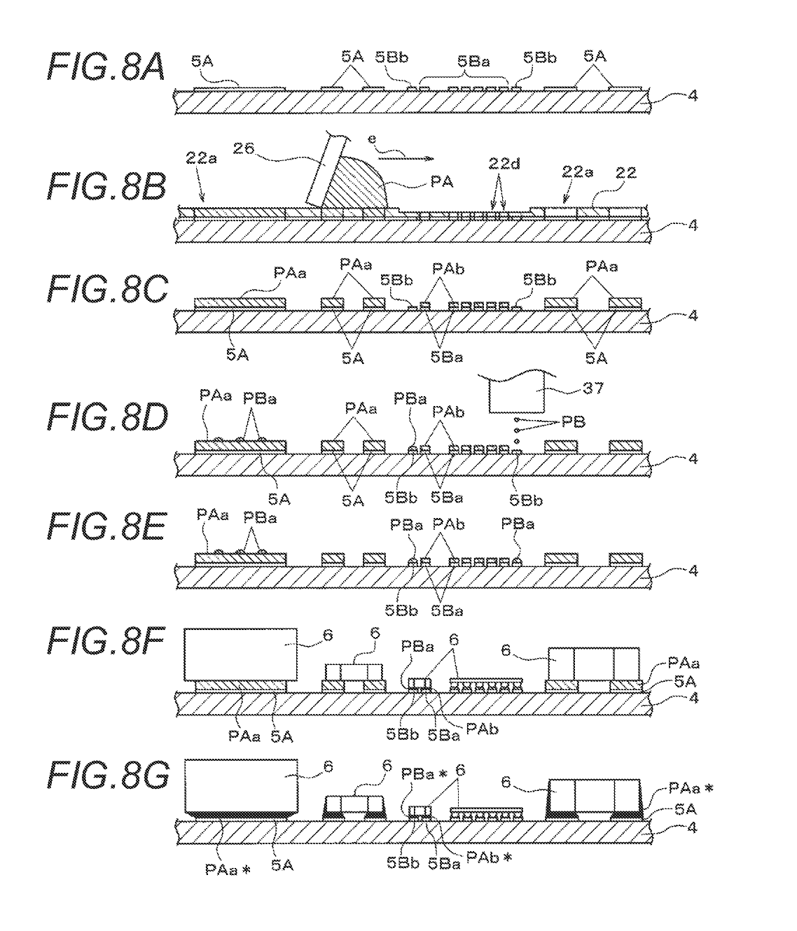

The electronic component mounting system 1 of the embodiment has the above-mentioned configuration, and subsequently, an electronic component mounting method will be described with reference to a flowchart shown in FIG. 7 and operation illustrative diagrams shown in FIGS. 8A to 8G. The respective control units (not illustrated) of the component mounting apparatus M1 to M7 control the respective mechanism of the component mounting apparatus M1 to M7 to perform operations that will be described below. In this example, among the plurality of tiny lands 5B that are continuously provided on the board 4 illustrated in FIG. 8A, the lands 5Bb at opposite ends are positioned in a region of the board 4, which overlaps the unstable region C of the mask plate 22. The second group includes the lands 5Bb as the second lands, and the first group includes the other lands 5A and 5Ba as the first lands.

First, the board supply apparatus M1 supplies the board 4 to the screen printing apparatus M2 (ST1: board supply step). Subsequently, the screen printing apparatus M2 supplies the solder PA to the board 4. That is, as illustrated in FIG. 8B, in a state where the board 4 is in contact with the lower surface of the mask plate 22, the squeegee 26 squeegees the solder PA supplied onto the upper surface of the mask plate 22 (along an arrow e). Accordingly, as illustrated in FIG. 8C, the solder PA is screen-printed on the board 4, and solder portions PAa and PAb are respectively formed on the first lands 5A and 5Ba via the pattern holes 22a and 22d.

Here, since the mask plate 22 is not provided with pattern holes that are positioned so as to correspond to the second lands 5Bb, the solder PA is not supplied to the second lands 5Bb. As such, the screen printing apparatus M2 supplies the solder paste to the board 4, using the mask plate 22 that includes the first part A, the second part B having a different thickness from that of the first part A, and the stepped portion 22c that is a boundary between the first part A and the second part B, and includes the pattern holes 22a and 22d respectively formed so as to correspond to the plurality of first lands 5A and 5Ba in the first part A and the second part B (ST2: first solder paste supply step).

After the operation of the screen printing apparatus M2 for the board 4 is complete, the board 4 is transported to the solder coating apparatus M3. Subsequently, the solder coating apparatus M3 supplies the solder PB to the board 4. That is, as illustrated in FIG. 8D, when the board 4 is located at the coating operation position, the dispenser 37 moves to a position above each of the second lands 5Bb. Subsequently, the dispenser 37 supplies a predetermined amount of the solder PB to the second lands 5Bb by discharging the solder PB via the discharge port 39. Accordingly, as illustrated in FIG. 8E, solder portions PBa are respectively formed on the second lands 5Bb. When the second lands 5Bb to which the solder is not supplied are present, the dispenser 37 moves to a position above each of the relevant second lands 5Bb, and supplies the solder PB to the relevant second lands 5Bb in the above-mentioned manner.

As such, the solder coating apparatus M3 supplies the solder paste to the plurality of second lands 5Bb, using the coating unit for coating the solder paste (ST3: second solder paste supply step). The solders PA and PB are supplied to all of the lands 5A, 5Ba, and 5Bb via the above-mentioned steps. Even when the first lands 5A and 5Ba to which the solder is insufficiently supplied during the screen printing are present, the dispenser 37 may move to a position above each of the relevant first lands 5A and 5Ba, and supplementarily coat the corresponding solder portions PAa and PAb with the solder PB by a shortfall of the solder. FIGS. 8D and 8E illustrate a state in which the solder portions PBa are formed on an upper surface of the solder portion PAa by supplementarily coating the first land 5A on a left side of the drawing sheet with the solder PB. Accordingly, it is possible to compensate for a deficiency in the supply of the solder PA to the first lands 5A

After the operation of the solder coating apparatus M3 for the board 4 is complete, the board 4 is transported to the first electronic component mounting apparatus M4. Subsequently, the first electronic component mounting apparatus M4 mounts the electronic components on the board 4. That is, as illustrated in FIG. 8F, when the board 4 is located at the mounting operation position, the mounting heads 60A and 60B (refer to FIG. 6) mount electronic components 6 on the desired lands 5A, 5Ba, and 5Bb. After the operation of the first electronic component mounting apparatus M4 for the board 4 is complete, the board 4 is transported to the second electronic component mounting apparatus M5, and the electronic components 6 are mounted on the board 4 in the above-mentioned manner. As such, the first electronic component mounting apparatus M4 and the second electronic component mounting apparatus M5 mount the electronic components 6 on the lands 5 to which the solder paste is supplied through the screen printing apparatus M2 and the coating unit (ST4: electronic component mounting step).

Subsequently, the board 4 with the electronic components mounted thereonto is transported to the reflow apparatus M6. The reflow apparatus M6 heats the transported board 4 per a predetermined heating profile (ST5: board heating step). Accordingly, as illustrated in FIG. 8G, the solder portions PAa, PAb, and PBa are melt and solidified, and solder bonding portions PAa.*, PAb*, PBa* are respectively formed between the electronic components 6 and the lands 5A, 5Ba, and 5Bb. A mounted board is completed via the above-mentioned steps. Thereafter, the mounted board is collected by the board collection apparatus M7 (ST6: board collection step).

As described above, the electronic component mounting system 1 of the embodiment serves to mount the electronic components 6 on the board 4 including the plurality of first lands 5A and 5Ba included in the first group and the plurality of second lands 5Bb included in the second group, using the solder paste. In an electronic component mounting method using the electronic component mounting system 1, when the mask plate 22 and the board 4 are aligned with each other, the solder PA is supplied to the first lands 5A and 5Ba positioned in other regions of the board 4 via the screen printing, the other regions not overlapping the unstable region C of the mask plate 22. The dispenser 37 supplies the solder PB to the second lands 5Bb positioned in the region of the board 4 via the coating, the region overlapping the unstable region C. Accordingly, it is possible to mount the electronic components 6 of various types or sizes on a piece of the board 4 at high density and with high quality, and improve productivity. In a design stage of the board, it is possible to improve the degree of freedom in the number of lands 5 or the disposition of the lands 5.

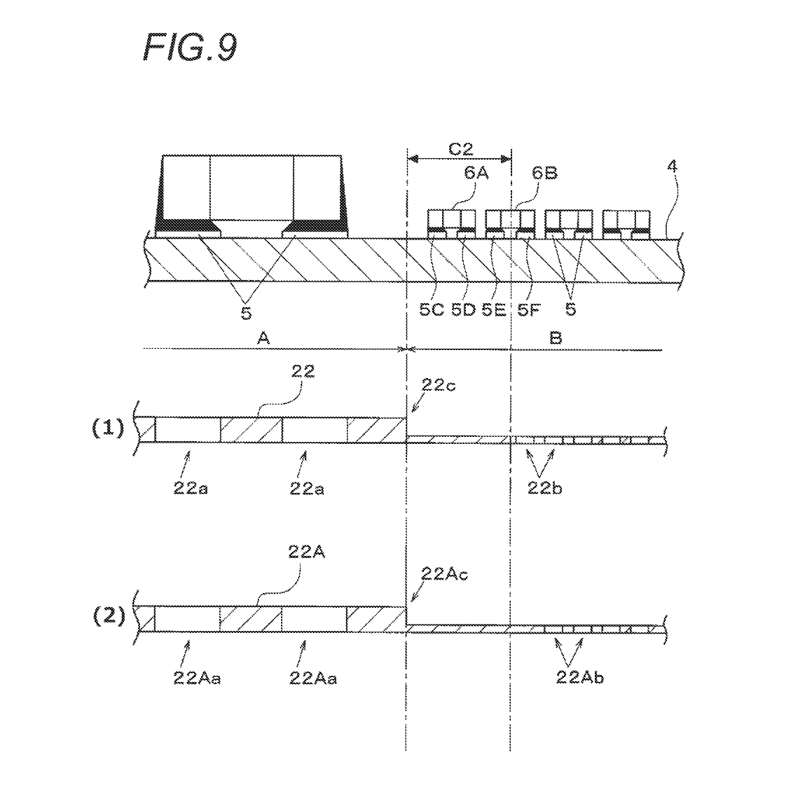

Subsequently, a plurality of methods of determining the second land will be described with reference to FIG. 9. Here, the methods of determining the second land in only a second unstable region C2 in the second part B of the mask plate 22 will be described. A first method is a method of determining the second land based on the position of the lands 5. That is, this method is the same as that described in the embodiment, and lands 5C, 5D, and 5E are determined as the second lands, and are positioned in a region of the board 4, which overlaps the second unstable region C2. When the second land is determined per the first method, the mask plate 22 illustrated in (1) of FIG. 9 is used. The mask plate 22 is not provided with pattern holes that are positioned so as to correspond to the lands 5C, 5D, and 5E, and the pattern holes 22a and 22d are formed in the mask plate 22 so as to correspond to the shapes and positions of the other lands 5.

A second method is a method of determining the second land based on the attributes of the electronic components 6. That is, when at least one of the plurality of lands 5 connected to a common electronic component 6 is positioned in the region of the board 4, which overlaps the second unstable region C2, all of the lands 5 connected to the electronic component 6 is selected as the second lands.

In an example illustrated in FIG. 9, the entirety of an electronic component 6A and part of an electronic component 6B are positioned in the region of the board 4, which overlaps the second unstable region C2. A plurality of the lands 5C and 5D connected to the electronic component 6A are also positioned in the region of the board 4, which overlaps the second unstable region C2. In contrast, between a plurality of the lands 5E and 5F connected to the electronic component 6B, the land 5E is positioned in the region of the board 4, which overlaps the second unstable region C2, and the land 5F is positioned in a region of the board 4, which is separate from the second unstable region C2. In the second method, not only the lands 5C, 5D, and 5E but also the land 5F are determined as the second lands. When the lands 5 are divided into groups, using the second method, the second group includes the entirety of the lands 5E and 5F connected to the single electronic component 6B that is mounted in a state where a part of the electronic component 6B is positioned in a region of the board 4, which overlaps the stepped portion 22c of the mask plate 22 and the vicinity of the stepped portion 22c, when the board 4 is brought into contact with the mask plate 22.

When the second lands are determined per the second method, a mask plate 22A illustrated in (2) of FIG. 9 is used. A stepped portion 22Ac is formed in the mask plate 22A at the same position at which the stepped portion 22 is formed in the mask plate 22. The mask plate 22A is not provided with pattern holes that are positioned so as to correspond to the lands 5C, 5D, 5E, and 5F, and pattern holes 22Aa and 22Ab are formed in the mask plate 22A so as to correspond to the shapes and positions of the other lands 5.

When the maintaining and managing of printing quality are considered as being important, the second lands are determined based on the second method. For example, in the case where mounting failure caused by solder supply failure is detected during the inspection of the mounted board, when the solder is supplied to the plurality of lands 5 connected to the common electronic component 6, using a common method, it is possible to quickly determine the root cause of the failure between the screen printing apparatus M2 and the solder coating apparatus M3. When the same type of solder is supplied to the plurality of lands 5 on which the common electronic component 6 is mounted, using a common method, printing quality is made further stable. As such, from the perspective of maintaining and managing printing quality, the second method is preferably adopted in which it is possible to supply the same type of solder to the lands 5 connected to the common electronic component 6 by a common method.

In contrast, since the attributes of the electronic components 6 are not taken into consideration in the first method, different types of solders may be supplied to the plurality of lands 5 connected to the common electronic component 6 by different methods. However, even in this case, when there are no particular problems with printing quality, it is possible to select the second land using the first method.

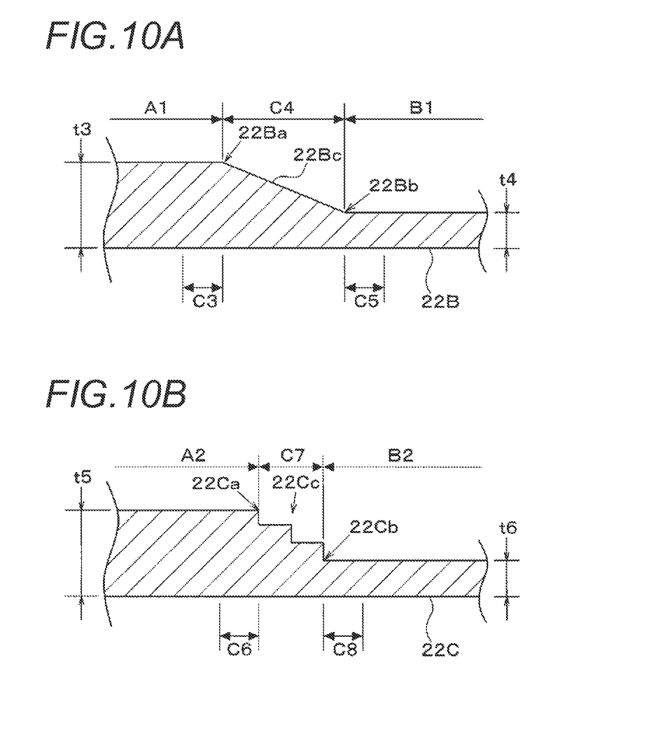

Subsequently, modification examples of the stepped portion of the mask plate will be described with reference to FIGS. 10A and 10B. In FIG. 10A, a first part A1 and a second part B1 are formed in a mask plate 22B, and the first part A1 has a thickness t3, and the second part B1 has a thickness t4 which is less than the thickness t3. A downward inclined surface 22Bc is formed from an edge 22Ba of the first part A1 to an edge 22Bb of the second part B1. In the mask plate 22B, the inclined surface 22Bc serves as the stepped portion that is a boundary between the first part A1 and the second part B1. The unstable region of the mask plate 22B includes a predetermined region C3 of the first part A1 in the vicinity of the stepped portion; a region C4 in which the stepped portion is formed; and a predetermined region C5 of the second part B1 in the vicinity of the stepped portion.

In FIG. 10B, a first part A2 and a second part B2 are formed in a mask plate 22C, and the first part A2 has a thickness t5, and the second part B2 has a thickness t6 which is less than the thickness t5. A stairs portion (multi-step portion) 22Cc is formed by cutting the mask plate 22C into multi-steps shape from an edge 22Cc of the first part A2 to an edge 22Cb of the second part B2. In the mask plate 22C, the stairs portion 22Cc serves as the stepped portion that is a boundary between the first part A2 and the second part B2. The unstable region of the mask plate 22C includes a predetermined region C6 of the first part A2 in the vicinity of the stepped portion; a region C7 in which the stepped portion is formed; and a predetermined region C8 of the second part B2 in the vicinity of the stepped portion.

The present invention is not limited to the embodiment described so far, and modifications may be made to the design insofar as the modifications do not depart from the scope of the present invention. For example, the component mounting line may include the screen printing apparatus M2, the solder coating apparatus M3, and the electronic component mounting apparatuses M4 and M5. The types or number of other component mounting apparatuses incorporated into the component mounting line are arbitrarily determined. The number of electronic component mounting apparatuses M4 and M5 is also arbitrarily determined. In the solder coating apparatus M3, a plurality of the X-axis tables 35 may be installed on the Y-axis table 33, and the dispenser 37 may be attached to each of the X-axis tables 35, and a plurality of the dispensers 37 may supply the solder PB to a piece of the board 4.

According to the present invention, it is possible to mount electronic components on a board at high density and with high quality, and improve productivity. The present invention is particularly useful in the electronic component mounting field.

What is claimed is:

1. An electronic component mounting method of using a solder paste to mount electronic components on a board provided with a plurality of first lands included in a first group and a plurality of second lands included in a second group, the method comprising:
supplying the solder paste to the board, using a mask plate which includes a first part, a second part having a different thickness from that of the first part, and a stepped portion that is a boundary between the first part and the second part, and includes pattern holes formed so as to correspond to the plurality of first lands in the first and second parts;
supplying the solder paste to the plurality of second lands, using a coating unit for coating the solder paste; and
mounting the electronic components on the first and second lands to which the solder paste is supplied, wherein
the second lands included in the second group are disposed in a region of the board, which overlaps the stepped portion of the mask plate and a vicinity of the stepped portion, when the solder paste is supplied using the mask plate.

2. The electronic component mounting method according to claim 1, wherein
the second group includes all of lands connected to a single electronic component that is mounted in a state where a part of the electronic component is positioned in the region of the board when the board is brought into contact with the mask plate.

3. An electronic component mounting system using a solder paste to mount electronic components on a board provided with a plurality of lands, the system comprising:
a screen printing apparatus that supplies the solder paste to a plurality of first specific lands of the board, using a mask plate that includes a first part, a second part having a different thickness from that of the first part, and a stepped portion that is a boundary between the first part and the second part, and includes pattern holes formed so as to correspond to the plurality of first specific lands in the first and second parts;
a coating unit which coats the solder paste on a plurality of second specific lands of the board which are positioned in a region of the board, the region overlapping the stepped portion of the mask plate and a vicinity of the stepped portion when the screen printing apparatus supplies the solder paste using the mask plate; and
an electronic component mounting apparatus that mounts the electronic components on the first and second specific lands to which the solder paste is supplied through the screen printing apparatus and the coating unit.

4. The electronic component mounting system according to claim 3, wherein
the coating unit is disposed in the electronic component mounting apparatus.
